(19) United States
(12) Patent Application Publication
(10) Pub. No.: US 2017/0346030 A1
(43) Pub. Date: Nov. 30, 2017

(54) THREE PRIMARY COLORS WHITE LIGHT OLED ELEMENT STRUCTURE, AND ELECTRO LUMINESCENT DEVICE AND DISPLAY ELEMENT THEREOF

(71) Applicant: Shenzhen China Star Optoelectronics Technology Co. Ltd., Shenzhen City (CN)

(72) Inventor: Kaifeng Zhou, Shenzhen City (CN)

(21) Appl. No.: 15/120,743

(22) PCT Filed: Jun. 15, 2016
(86) PCT No.: PCT/CN2016/085796

§ 371 Date: Aug. 23, 2016

(30) Foreign Application Priority Data
May 24, 2016 (CN) 201610350045.0

(51) Int. Cl. H01L 51/50

(52) U.S. Cl. CPC H01L 51/504; H01L 51/5004

(57) ABSTRACT

Disclosed is a three primary colors white light OLED element structure. The element structure includes: a substrate, an anode on the substrate, a P type doping layer on the anode, a first light emitting layer on the P type doping layer, a first N type semiconductor material layer on the first light emitting layer, a first P type semiconductor material layer on the first N type semiconductor material layer, a second light emitting layer on the first P type semiconductor material layer, a second N type semiconductor material layer on the second light emitting layer, a second P type semiconductor material layer on the second N type semiconductor material layer, a third light emitting layer on the second P type semiconductor material layer, a N type doping layer on the third light emitting layer, and a cathode on the N type doping layer.

### FIELD OF THE INVENTION

The present invention relates to a display technology field, and more particularly to a three primary colors white light OLED element structure, and an electro luminescent device and a display element thereof.

### BACKGROUND OF THE INVENTION

Organic Light-Emitting Device (OLED) possesses the advantages, such as fast response speed, wide view angle, low power consumption, light weight and low power consumption, and draws lots of attentions in the industry. Organic Light Emitting Diode (OLED) is a display technology which has great prospects for development. It does not only possess extremely excellent display performance but also properties of self-illumination, simple structure, ultra thin, fast response speed, wide view angle, low power consumption and capability of realizing flexible display, and therefore is considered as “dream display”. With the much smaller investment for the production apparatuses than the TFT-LCD, it has been favored by respective big display makers and has become the main selection of the third generation display element. At present, the OLED has reached the point before mass production. With the further research and development, the new technologies constantly appear, and someday, there will be a breakthrough for the development of the OLED display elements.

For realizing the full color of the OLED display device, one way is to achieve it by laminating the WOLED (White Organic Light Emitting Diode) and the CF (Color Filter).The lamination process of the WOLED and CF does not require accurate mask process to achieve the high resolution of the OLED display device. The white light OLED (WOLED) can be the light source applied in the lighting field. The full color display can be achieved by white light OLED plus color filter to be applied in the display field, and has significant meanings.

The present WOLED is mainly achieved by dual complementary colors or three primary colors mixture. Please refer to FIG. 1. which is a three primary colors WOLED element structure according to prior art. The three primary colors WOLED element structure mainly comprises: a substrate 1, an anode 2 forming on the substrate 1, a Hole Injection Layer 3 formed on the anode 2, a Hole Transporting Layer 4 formed on the Hole Injection Layer 3, a red light layer 5 formed on the Hole Transporting Layer 4, a green light layer 6 formed on the red light layer 5, a blue light layer 7 formed on the green light layer 6, an Electron Transport Layer 8 formed on the blue light layer 7, an Electron Injection Layer 9 formed on the Electron Transport Layer 8 and a cathode 10 formed on the Electron Injection Layer 9, and the red light layer 5, green light layer 6 and the blue light layer 7 form three primary colors mixture to output the white light from the side of the substrate 1. Consequently, the present three primary colors white light WOLED forms the white light by stacking up the red, green, blue three primary colors materials. The purity and the color rendering of the formed white light are higher. However, the element structure and the process are complicated, and the drive voltage of the white light element of such multiple layers structure is higher due to the existence of the interfaces of electrode/organics, organics/organics, and the carrier injection and the unbalanced recombination result in the descend of the current efficiency of the white light element. These issues will obstruct the commercialization of this three primary colors white light OLED element. In view of the above problems, there is a need to provide a three primary colors white light OLED element structure to solve the aforesaid technical issues.

### SUMMARY OF THE INVENTION

Therefore, an objective of the present invention is to provide a three primary colors white light OLED element structure to reduce the drive voltage of the element to promote the power efficiency of the white light element.

Another objective of the present invention is to provide an electro luminescent device, comprising a three primary colors white light OLED element structure to reduce the drive voltage of the element to promote the power efficiency of the white light element.

Another objective of the present invention is to provide a display element, comprising a three primary colors white light OLED element structure to reduce the drive voltage of the element to promote the power efficiency of the white light element.

For realizing the aforesaid objectives, the present invention provides a three primary colors white light OLED element structure, comprising: a substrate, an anode formed on the substrate, a P type doping layer formed on the anode, a first light emitting layer formed on the P type doping layer, a first N type semiconductor material layer formed on the first light emitting layer, a first P type semiconductor material layer formed on the first N type semiconductor material layer, a second light emitting layer formed on the first P type semiconductor material layer, a second N type semiconductor material layer formed on the second light emitting layer, a second P type semiconductor material layer formed on the second N type semiconductor material layer, a third light emitting layer formed on the second P type semiconductor material layer, a N type doping layer formed on the third light emitting layer, and a cathode formed on the N type doping layer.

The P type doping layer is formed by doping P type dopant in hole transport main material.

The hole transport main material is organic material.

The N type doping layer is formed by doping N type dopant in electron transport main material.

The electron transport main material is organic material.

The first P type semiconductor material layer and the second P type semiconductor material layer are formed by donor type material, and the first N type semiconductor material layer and the second N type semiconductor material layer are formed by acceptor type material.

Interfaces of heterojunction are respectively formed at an interface of the first N type semiconductor material layer and the first P type semiconductor material layer, and at an interface of the second N type semiconductor material layer and the second P type semiconductor material layer.

The first light emitting layer is a blue light emitting layer, and the second light emitting layer is a green light emitting layer, and the third light emitting layer is a red light emitting layer.

The present invention further provides an electro luminescent device, comprising the aforesaid three primary colors white light OLED element structure.

The present invention further provides a display element, comprising the aforesaid three primary colors white light OLED element structure.

In conclusion, in the three primary colors white light OLED element structure, and the electro luminescent device and the display element thereof, the doping layer is introduced to form the P-I-N structure to effectively reduce the drive voltage of the element, and meanwhile, the heterojunction structure is formed at the interface of the two light emitting layers to prevent the exciton annihilation at the interface and to balance the carrier concentrations of the respective light emitting units for raising the current efficiency of the element to ultimately promote the power efficiency of the white light element.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a three primary colors WOLED element structure according to prior art;

FIG. 2 is a three primary colors white light WOLED element structure according to the present invention;

FIG. 3 is a principle diagram of N type (a) and P type (b) doping in the three primary colors white light WOLED element structure according to the present invention;

FIG. 4 is a principle diagram of forming heterojunction at the interface of P type organics/N type organics to achieve exciton separation in the three primary colors white light WOLED element structure according to the present invention.

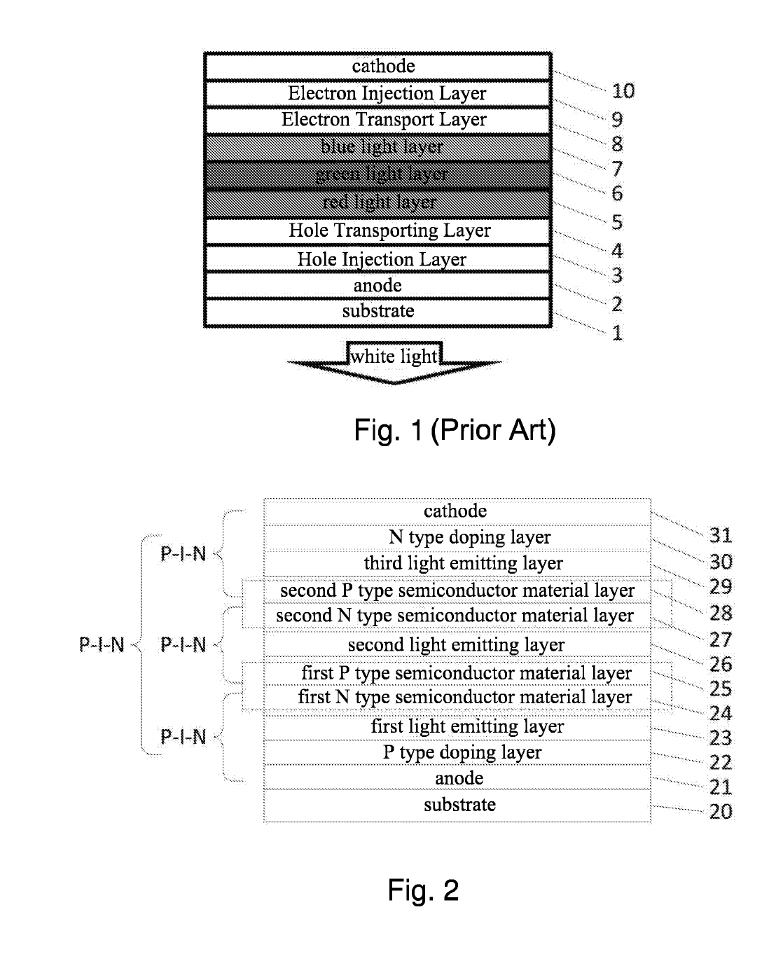

### DETAILED DESCRIPTION OF PREFERRED EMBODIMENTS

Please refer to FIG. 2, which is a three primary colors white light WOLED element structure according to the present invention. The three primary colors white light OLED element structure comprises: a substrate 20, an anode 21 forming on the substrate 20, a P type doping layer 22 formed on the anode 21, a first light emitting layer 23 formed on the P type doping layer 22, a first N type semiconductor material layer 24 formed on the first light emitting layer 23, a first P type semiconductor material layer 25 formed on the first N type semiconductor material layer 24, a second light emitting layer 26 formed on the first P type semiconductor material layer 25, a second N type semiconductor material layer 27 formed on the second light emitting layer 26, a second P type semiconductor material layer 28 formed on the second N type semiconductor material layer 27, a third light emitting layer 29 formed on the second P type semiconductor material layer 28, a N type doping layer 30 formed on the third light emitting layer 29, and a cathode 31 formed on the N type doping layer 30. In one preferred embodiment, the first light emitting layer 23 can a blue light emitting layer, and the second light emitting layer 26 can a green light emitting layer, and the third light emitting layer 29 can a red light emitting layer.

The present invention forms the white light by stacking up three primary color light emitting materials, the first light emitting layer 23, the second light emitting layer 26 and the third light emitting layer 29. As shown in FIG. 2, the entire element appears P-I-N structure, and three P-I-N structures are formed among the light emitting units.

One layer of P type doping layer 22 is at least formed in the present invention, which is formed by doping P type dopant in hole transport main material. The main material is organic material, and the dopant is not restricted to be organic material.

One layer of N type doping layer 30 is at least formed in the present invention, which is formed by doping N type dopant in electron transport main material. The main material is organic material, and the dopant is not restricted to be organic material.

At least two hetero layers are formed in the present invention, which are positioned among every two light emitting layers of the three kinds of light emitting layers. Each kind of heterojunction forms at least formed a layer of heterojunction layer by adjacently arranging or mixing the P type semiconductor layer and the N type semiconductor layer. Please refer to FIG. 2. Specifically, interfaces of heterojunction are respectively formed at an interface of the first N type semiconductor material layer 24 and the first P type semiconductor material layer 25, and an interface of the second N type semiconductor material layer 27 and the second P type semiconductor material layer 28.

The present invention forms the white light by stacking up three primary color light emitting materials to promote the color rendering. The P-I-N structure design in the element structure is beneficial to reduce the drive voltage of the multiple layers element. The effective separation of exciton at the interface is realized by introducing the heterojunction layers among the light emitting units to raise the exciton utilization efficiency and to balance the carrier concentrations of the respective light emitting units to ultimately promote the power efficiency of the white light element.

The three primary colors white light WOLED element structure according to the present invention can be applied in an electro luminescent device to form the electro luminescent device including the three primary colors white light WOLED element structure to utilize the advantage.

The three primary colors white light WOLED element structure according to the present invention can be applied in a display element to form the display element including the three primary colors white light WOLED element structure to utilize the advantage.

The P type doping layer 22 of the present invention is positioned at the side of the anode 21 to realize the injection and transport of the holes from the anode 21 to the organic layer: the P type doping layer 22 comprises the main material and the P type dopant, and the main material is the material that the hole mobility is higher, and the P type dopant has deeper HOMO (Highest Occupied Molecular Orbital) energy level to form the charge transfer with the main material.

The N type doping layer 30 is positioned at the side of the cathode 31 to realize the injection and transport of the electrons from the cathode 31 to the organic layer: the N type doping layer 30 comprises the main material and the N type dopant, and the main material is the material that the electron mobility is higher, and the N type dopant has shallower HOMO (Lowest Occupied Molecular Orbital) energy level to form the charge transfer with the main material.

The heterojunction layers are positioned among every two light emitting layers of the first light emitting layer 23, the second light emitting layer 26 and the third light emitting layer 29 (red/green/blue), and is formed by adjacently arranging the P type semiconductor layer and the N type semiconductor layer. The heterojunction is formed at the P/N interface to achieve the exciton separation to be electron and hole: the P type semiconductor material layers are donor type material, and the N type semiconductor material layers are acceptor type material.

The entire three primary colors white light WOLED element structure is shown in FIG. 2. The entire element appears to be the P-I-N structure, and the light emitting unit R, the light emitting unit G and the light emitting B also construct the P-I-N structures. It is beneficial for reducing the drive voltage of the entire element.

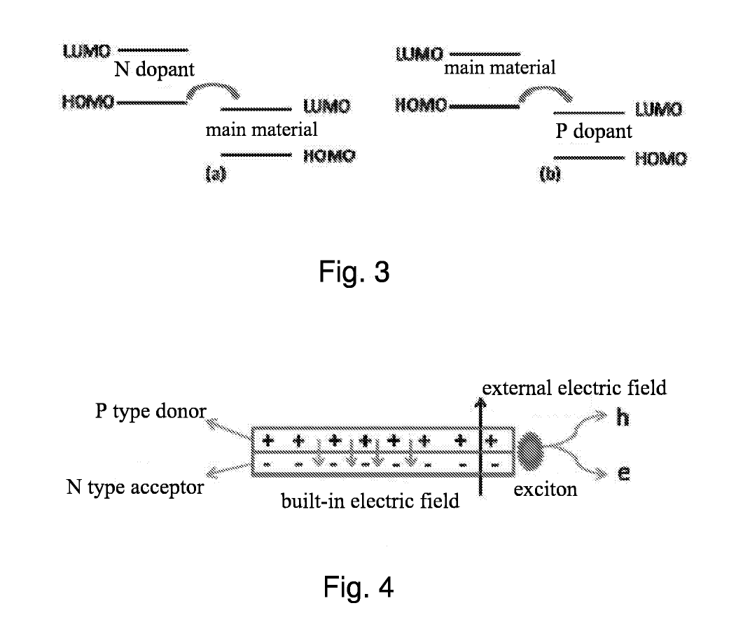

Please refer to FIG. 3, which is a principle diagram of N type (a) and P type (b) doping in the three primary colors white light WOLED element structure according to the present invention. The present invention can reduce the drive voltage by P type doping or N type doping to increase the carrier injection concentration. The proper doping material often can change the electrode/organic interface properties, such as interface fermi level shift, interface band bending to reduce the injection barrier. The charge transfer effect between the doping material and the main material raises the concentration of the holes or electrons in the main material.

Please refer to FIG. 4, which is a principle diagram of forming heterojunction at the interface of P type organics/N type organics to achieve exciton separation in the three primary colors white light WOLED element structure according to the present invention. The present invention achieves exciton separation by forming heterojunction at the interface of P type organics/N type organics. The donor and the acceptor have different electronic affinities and ionization potentials. When two materials having different electronic affinities and ionization potentials contact, the electric potential difference generates at the contact interface, and the electric potential difference can form a local electric field. Because the LUMO value of the donor is higher than the LUMO value of the acceptor, under the function of the local electric field, the exciton migrates to this interface, and the electron falls from the conduction band of the donor to the conduction band of the acceptor, and thus to destroy the electron-hole pair in the original exciton to dissociate the exciton to be a hole and an electron.

In one preferred embodiment, the manufacture method of the three primary colors white light WOLED element structure according to the present invention is:

1. providing a substrate (glass or plastic), and sequentially depositing an anode (100-500 nm), a P type doping layer (5-20 nm), a blue light emitting layer 1 (30-100 nm), a N type semiconductor layer 1 (5-10 nm), a P type semiconductor layer 2 (5-10 nm), a green light emitting layer 2 (30-100 nm), a N type semiconductor layer 3 (5-10 nm), a P type semiconductor layer 4 (5-10 nm), a red light emitting layer 3 (30-100 nm), a N type doping layer (5-20 nm), a cathode (100-500 nm) thereon;

2. forming films of the thin films of the respective functions with vacuum deposition and solution method;

3. Material of the anode can select the high work function metal, such as ITO, Au; the cathode can select the low work function alloy, such as Ba/Al, Mg/Ag, and the blue light material can select the PFO, GO, Firpic, and the green light material can select P-PPV, Ir(ppy)3, and the red light material can select MEH-PPV, Ir(MDQ)2(acac); the P type doping layer can be P type dopant: hole transport main material=0.1%-99% (mass ratio), wherein the main material can be such as PVK, NPB, m-MTDATA, and the P type dopant can be F4-TCNQ, ReO3, Fe2O3; the N type dopant can be N type dopant: electron transport main material=0.1%-99% (mass ratio), wherein the main material can be such as PFN, TmPyPB, TpPyPB, and the N type dopant can be Cs2CO3, Li2CO3, Li3N; the P type semiconductor material layer can be donor material, such as P3HT, PTB7, and the type semiconductor material layer can be acceptor material, such as PCBM, PC71BM.

4. the entire element appears to be the P-I-N structure, and the red light emitting unit 1, the green light emitting unit 2 and the blue light emitting 3 also construct the P-I-N structures (such as structure of P type layer/light emitting layer/N type layer).

The series connection of the three P-I-N structures formed by the present invention is to utilize the P type and N type doping effect to raise the concentrations of holes and electrons, and meanwhile to reduce the injection barrier of the interface charge. Besides, the heterojunction layer is introduced among the light emitting units to realize the effective separation of exciton at the interface. In the present invention, the P type semiconductor material layers are donor type material, and the N type semiconductor material layers are acceptor type material, and exciton separation can be realized. The reduction of the element drive voltage can be realized with the doping effect of the electrode interface, and a plurality of heterojunction structure full utilize excitons of the interfaces of the respective light emitting units to achieve the three primary colors light emitting material high efficiency light emission and the mixture for emitting the white light.

In conclusion, the three primary colors white light OLED element structure, and the electro luminescent device and the display element thereof utilizes the principle of color to form the white light by complementary color material luminescence superposition, and the doping layer is introduced to form the P-I-N structure to effectively reduce the drive voltage of the element, and meanwhile, the heterojunction structure is formed at the interface of the two light emitting layers to prevent the exciton annihilation at the interface and to balance the carrier concentrations of the respective light emitting units for raising the current efficiency of the element to ultimately promote the power efficiency of the white light element.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

1. A display element, comprising a A-three primary colors white light OLED element structure, comprising: a substrate, an anode formed on the substrate, a P type doping layer formed on the anode, a first light emitting layer formed on the P type doping layer, a first N type semiconductor material layer formed on the first light emitting layer, a first P type semiconductor material layer formed on the first N type semiconductor material layer, a second light emitting layer formed on the first P type semiconductor material layer, a second N type semiconductor material layer formed on the second light emitting layer, a second P type semiconductor material layer formed on the second N type semiconductor material layer, a third light emitting layer formed on the second P type semiconductor material layer, a N type doping layer formed on the third light emitting layer, and a cathode formed on the N type doping layer; wherein the P type doping layer, the first light emitting layer and the first N type semiconductor material layer construct a P type layer/light emitting layer/N type layer structure, the first P type semiconductor material layer, the second light emitting layer and the second N type semiconductor material layer construct a P type layer/light emitting layer/N type layer structure and the second P type semiconductor material layer, the third light emitting layer and the N type doping layer construct a P type layer/light emitting layer/N type layer structure;
wherein the three primary colors white light OLED element structure also construct a P type layer/light emitting layer/N type layer structure.

2. The three primary colors white light OLED element structure according to claim 1, wherein the P type doping layer is formed by doping P type dopant in hole transport main material.

3. The three primary colors white light OLED element structure according to claim 2, wherein the hole transport main material is organic material.

4. The three primary colors white light OLED element structure according to claim 1, wherein the N type doping layer is formed by doping N type dopant in electron transport main material.

5. The three primary colors white light OLED element structure according to claim 4, wherein the electron transport main material is organic material.

6. The three primary colors white light OLED element structure according to claim 1, wherein the first P type semiconductor material layer and the second P type semiconductor material layer are formed by donor type material, and the first N type semiconductor material layer and the second N type semiconductor material layer are formed by acceptor type material.

7. The three primary colors white light OLED element structure according to claim 1, wherein interfaces of heterojunction are respectively formed at an interface of the first N type semiconductor material layer and the first P type semiconductor material layer, and at an interface of the second N type semiconductor material layer and the second P type semiconductor material layer.

8. The three primary colors white light OLED element structure according to claim 1, wherein the first light emitting layer is a blue light emitting layer, and the second light emitting layer is a green light emitting layer, and the third light emitting layer is a red light emitting layer.

9-10. (canceled)
